(19) United States
(12) Patent Application Publication
(10) Pub. No.: US 2008/0179596 A1
(43) Pub. Date: Jul. 31, 2008

(54) Thin film transistor, organic light emitting device including thin film transistor, and manufacturing method thereof

(76) Inventors: Kyu-Sik Cho, Suwon-si (KR); Jong-Moo Huh, Hwaseong-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/008,519

(22) Filed: Jan. 11, 2008

(30) Foreign Application Priority Data
Jan. 26, 2007 (KR) 10-2007-0008264

(51) Int. Cl. H01L 29/04; H01L 21/336

(52) U.S. Cl. 257/59; 257/66; 438/166; 257/E29.003; 257/E21.413

(57) ABSTRACT

The present invention relates to a thin film transistor (TFT), an organic light emitting diode (OLED) display having the TFT, and a manufacturing method thereof. The manufacturing method includes: forming a pair of ohmic contacts including amorphous silicon that contains an impurity; forming a semiconductor member including amorphous silicon; crystallizing the ohmic contacts and the semiconductor member; forming an input electrode and an output electrode on the ohmic contacts; forming an insulating layer on the input electrode, the output electrode, and the blocking member; forming a control electrode on the insulating layer; forming a switching thin film transistor; and forming an organic light emitting diode connected to the output electrode.

### CROSS-REFERENCE TO RELATED APPLICATION

This application claims priority to and the benefit of Korean Patent Application No. 10-2007-0008264 filed in the Korean Intellectual Property Office on Jan. 26, 2007, the entire contents of which are incorporated herein by reference.

### BACKGROUND OF THE INVENTION

(a) Technical Field

The present invention relates to a thin film transistor, an organic light emitting diode (OLED) display including the thin film transistor, and a manufacturing method of the OLED display.

(b) Discussion of the Related Art

In general, in an active type of flat panel display, a plurality of pixels are arranged in a matrix format, and an image is displayed by controlling luminance of each pixel according to given display information. Among the spectrum of flat panel displays, organic light emitting diode (OLED) displays are upcoming for a next generation display that is superior to a liquid crystal display (LCD) since the OLED display is a self-emitting type display and requires low power features, a wide viewing angle, and responds rapidly to control signals.

Each pixel of the OLED display includes an organic light emitting element, a driving transistor for driving the organic light emitting element, and a switching transistor for applying a data voltage to the driving transistor. The transistors are implemented as thin film transistors (TFTs), which can be either polycrystalline silicon TFTs or amorphous silicon TFTs according to the type of active layer.

In the case of the polycrystalline silicon TFT, however, a polycrystalline silicon layer is generally disposed at the lowermost position and an ohmic contact layer and electrodes are formed thereon. Then a gate insulating layer and a gate electrode are formed.

In this structure, a channel region of the polycrystalline silicon layer can easily have an impurity introduced therein or it may be easily damaged during a crystallization process or in follow-up processes. When an impurity is introduced, the surface can be partially shaved, but the polycrystalline silicon layer must be thick enough to allow the shaving and the thickness may not be uniform after the shaving.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to reduce damage to a channel region of a thin film transistor and reduce introduction of an impurity.

An exemplary thin film transistor according to one embodiment of the present invention includes first and second ohmic contacts, a blocking member, an input electrode, an output electrode, an insulating layer, and a control electrode. The first and second ohmic contacts are formed on a substrate. The input electrode is formed on the first ohmic contact. The output electrode is formed on the second ohmic contact. The insulating layer is formed on the input electrode, the output electrode, and the blocking member. The control electrode is formed on the insulating layer and placed on the semiconductor.

The semiconductor member may include crystalline silicon, particularly polycrystalline silicon, and the first and second ohmic contacts may include crystalline silicon that contains an impurity.

The blocking member may be made of a material that contains fluorine, such as SiOF.

The blocking member may entirely cover the semiconductor member, and particularly, the blocking member and the semiconductor member may have the same planar shape.

The input electrode and the output electrode may be separated from the semiconductor member.

An exemplary organic light emitting diode (OLED) display according to another embodiment of the present invention includes: a pair of first ohmic contacts formed on a substrate; a first semiconductor formed on the first ohmic contacts and the substrate; a blocking member formed on the first semiconductor; a first insulating layer formed on a first input electrode, a first output electrode, and the blocking member; a first control electrode formed on the first insulating layer and placed on the first semiconductor member; a second control electrode formed on the first insulating layer and separated from the first control electrode; a second insulating layer formed on the first and second control electrodes; a second semiconductor member formed on the second insulating layer, and placed on the second control electrode; a second ohmic contact formed on the second semiconductor member; a second input electrode and a second output electrode formed on the second ohmic contact; a third insulating layer formed on the second input electrode, the second output electrode, and the second semiconductor member; and an organic light emitting diode formed on the third insulating layer, and connected to the first output electrode.

The first semiconductor may include crystalline silicon, particularly polycrystalline silicon, the second semiconductor member may include amorphous silicon, and the first ohmic contact may include polycrystalline that contains an impurity.

The blocking member may be made of a material that contains fluorine, such as SiOF.

The blocking member and the first semiconductor may have the same planar shape.

The first input electrode and the first output electrode may be separated from the semiconductor member.

The OLED display may further include a driving voltage line connected to the first input electrode, a data line connected to the second input electrode, and a gate line connected to the first control electrode.

The first control electrode and the second output electrode may be connected to each other.

An exemplary manufacturing method according to another embodiment of the present invention manufactures a thin film transistor. The manufacturing method includes: forming a pair of ohmic contacts including amorphous silicon that contains an impurity; forming a semiconductor member including amorphous silicon; crystallizing the ohmic contacts and the semiconductor member; forming an input electrode and an output electrode on the ohmic contacts; forming an insulating layer on the input electrode, the output electrode, and the blocking member; and forming a control electrode on the insulating layer.

The manufacturing method according to the embodiment of the present invention further include forming a switching thin film transistor and forming an organic light emitting diode connected to the output electrode.

The crystallizing of the ohmic contacts and the semiconductor member may include performing a heat treatment process on the ohmic contacts and the semiconductor member.

The blocking member may be made of a material that contains fluorine, such as SiOF.

One of the blocking member and the semiconductor member may be formed by a photolithography process.

### BRIEF DESCRIPTION OF THE DRAWINGS

FIG. 1 is an equivalent circuit diagram of an organic light emitting device according to an exemplary embodiment of the present invention.

FIG. 2 is a layout view of the organic light emitting device according to the exemplary embodiment of the present invention.

FIG. 3 is a cross-sectional view of the organic light emitting device of FIG. 2, taken along line III-III.

FIG. 4 is a cross-sectional view of t an organic light emitting device similar to that of FIG. 2, taken along line III-III, but with a slightly modified structure.

FIG. 5, FIG. 7, FIG. 9, FIG. 11, FIG. 13, FIG. 15, FIG. 17, and FIG. 19 are layout views of intermediate stages of a manufacturing process of the OLED display of FIG. 2 and FIG. 3 according to an exemplary embodiment of the present invention.

FIG. 6 is a cross-sectional view of the OLED display of FIG. 5, taken along line VI-VI.

FIG. 8 is a cross-sectional view of the OLED display of FIG. 7, taken along line VIII-VIII.

FIG. 10 is a cross-sectional view of the OLED display of FIG. 9, taken along line X-X.

FIG. 12 is a cross-sectional view of the OLED display of FIG. 11, taken along line XII-XII.

FIG. 14 is a cross-sectional view of the OLED display of FIG. 13, taken along line XIV-XIV.

FIG. 16 is a cross-sectional view of the OLED display of FIG. 15, taken along line XVI-XVI.

FIG. 18 is a cross-sectional view of the OLED display of FIG. 17, taken along line XVIII-XVIII.

FIG. 20 is a cross-sectional view of the OLED display of FIG. 19, taken along line XX-XX.

FIG. 21 is an OLED display according to another exemplary embodiment of the present invention.

FIG. 22 is a cross-sectional view of the OLED display of FIG. 21, taken along line XXII-XXII.

### DETAILED DESCRIPTION OF THE EMBODIMENTS

The present invention is described more fully hereinafter with reference to the accompanying drawings, in which exemplary embodiments of the invention are shown.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

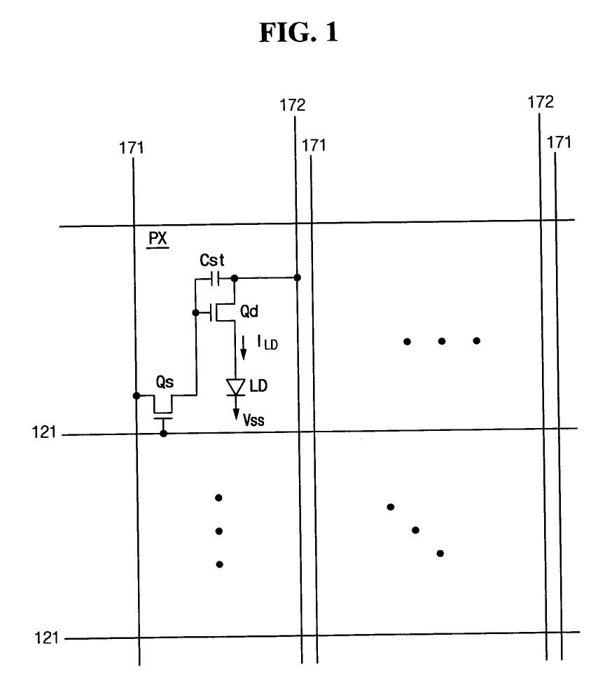

First, an organic light emitting diode (OLED) display according to an exemplary embodiment of the present invention will be described in further detail with reference to FIG. 1.

FIG. 1 is an equivalent circuit diagram of the OLED display according to the exemplary embodiment of the present invention.

Referring to FIG. 1, the OLED display includes a plurality of signal lines 121, 171, and 172 and a plurality of pixels PX connected to the signal lines and arranged approximately in a matrix format.

The signal lines include a plurality of gate lines 121 for transmitting gate signals (or scan signals), a plurality of data lines 171 for transmitting data signals, and a plurality of driving voltage lines 172 for transmitting a driving voltage. The gate lines 121 extend substantially in a row direction, and they are substantially parallel to one another. The data lines 171 and the driving voltage lines 172 extend substantially in a column direction, and they are substantially parallel to one another.

Each pixel PX includes a switching transistor Qs, a driving thin film transistor Qd, a storage capacitor Cst, and an organic light emitting diode (OLED) LD.

The switching transistor Qs includes a control terminal, an input terminal, and an output terminal. The control terminal is connected to a gate line 121, the input terminal is connected to a data line 171, and the output terminal is connected to the driving TFT Qd. The switching transistor Qs transmits the data signal received from the data line 171 to the driving transistor Qd in response to a scan signal received from the gate line 121.

The driving transistor Qd also includes a control terminal, an input terminal, and an output terminal. The control terminal is connected to the switching transistor Qs, the input terminal is connected to a driving voltage line 172, and the output terminal is connected to the OLED LD. The driving transistor Qd flows an output current ILD having an amplitude that varies according to a voltage formed between the control terminal and the output terminal.

The storage capacitor Cst is connected between the control terminal and the input terminal of the driving transistor Qd. The storage capacitor Cst charges the data signal applied to the control terminal of the driving transistor Qd and sustains the charged data signal after the switching transistor Qs is turned off.

The OLED LD includes an anode connected to the output terminal of the driving transistor Qd and a cathode connected to a common voltage Vss. The OLED LD displays images by emitting light with varying intensity according to the output current ILD of the driving transistor Qd.

The switching transistor Qs and the driving transistor Qd are n-channel field effect transistors (FETs). However, at least one of the switching transistor Qs and the driving transistor Qd may be a p-channel FET. Also, the coupling relationship between the transistors Qs and Qd, the storage capacitor Cst, and the OLED LD may be changed.

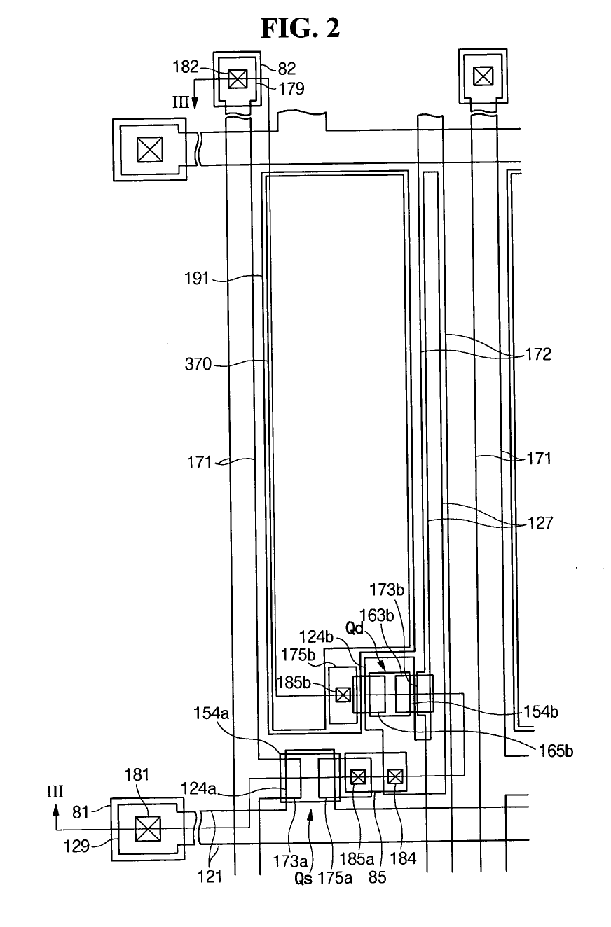

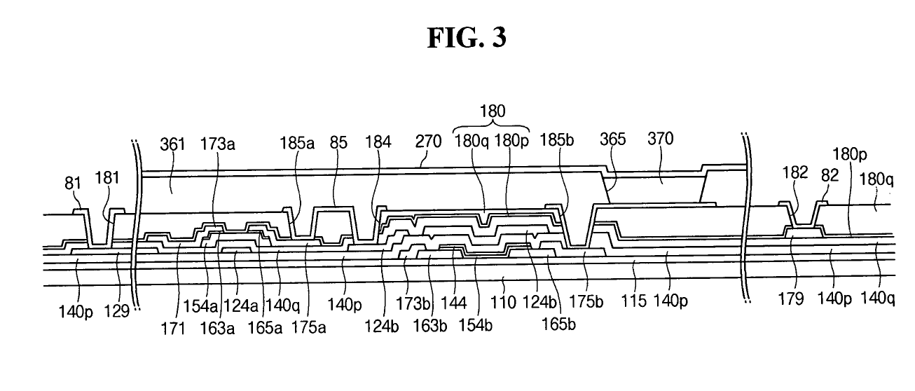

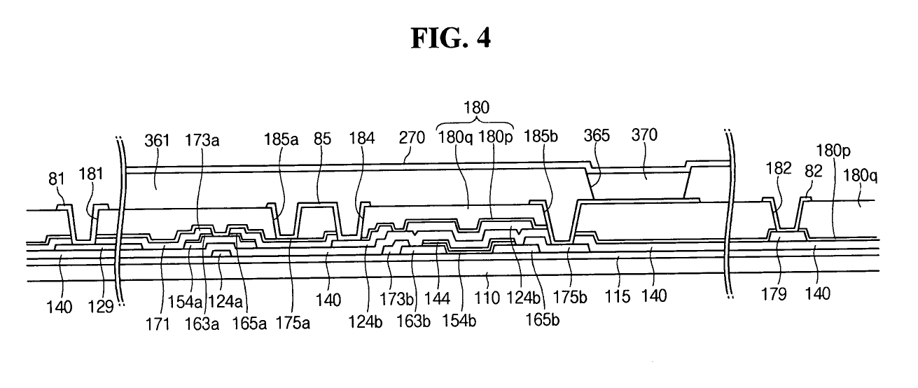

The detailed structure of the OLED display of FIG. 1 will be further described with reference to FIG. 2, FIG. 3, and FIG. 4.

FIG. 2 is a layout view of the OLED display according to the exemplary embodiment of the present invention, FIG. 3 is a cross-sectional view of an exemplary embodiment of the OLED display of FIG. 2, taken along the line III-III, and FIG. 4 is a cross-sectional view of another exemplary embodiment of the OLED display of FIG. 2, taken along the line III-Ill.

The following description is focused on the cross-sectional view of FIG. 3, and in the description of FIG. 4, only parts that are different from the cross-sectional view of FIG. 3 will be described.

A buffer layer 115 made of silicon oxide (SiOx) is formed on an insulation substrate 110 that is made of transparent glass or plastic.

On the buffer layer 115, a plurality of pairs of ohmic contact islands 163b and 165b are formed.

The ohmic contacts 163b and 165b may be made of crystalline semiconductor such as n+ polycrystalline silicon in which an n-type impurity is highly doped.

A plurality of first semiconductor islands 154b are formed on the respective pairs of ohmic contacts 163b and 165b and the buffer layer 115 between each pair of ohmic contacts 163b and 165b. Each of the first semiconductor islands 154b may be made of polycrystalline silicon, and they partially cover the ohmic contacts 163b and 165b.

A plurality of blocking members 144 are formed on the first semiconductor islands 154b. Each blocking member 144 entirely covers an upper surface of the first semiconductor island 154b, and can be formed with substantially the same pattern as the first semiconductor island 154b. The blocking members 144 may be made of a fluorine-containing insulation material, for example SiOF. According to another exemplary embodiment of the present invention, the blocking members 144 can be made of silicon nitride (SiNx) or silicon oxide (SiOx).

A plurality of driving voltage lines 172 and a plurality of first output electrodes 175b are formed on the buffer layer 115 and the ohmic contacts 163b and 165b.

The driving voltage lines 172 transmit a driving voltage and substantially extend in a vertical direction. Each of the driving voltage lines 172 includes a first input electrode 173b that contacts the ohmic contact 163b.

The first output electrodes 175b are separated from the driving voltage lines 172, and contact the ohmic contact islands 165b and the buffer layer 115.

Each pair of the ohmic contacts 163b and 165b is partially exposed without being covered by the driving voltage line 172, the first output electrode 175b, and the first semiconductor island 154b.

The driving voltage lines 172 and the first output electrodes 175b may be made of a refractory metal such as molybdenum (Mo), chromium (Cr), tantalum (Ta), or titanium (Ti), or an alloy of them. The driving voltage lines 172 and the first output electrodes 175b may have a multi-layered structure having a refractory metal layer (not shown) and a low-resistive conductive layer (not shown). Examples of the multi-layered structure include a double layer of a chromium or molybdenum (alloy) lower layer and an aluminum (alloy) upper layer, and a triple layer of a molybdenum (alloy) lower layer, an aluminum (alloy) middle layer, and a molybdenum (alloy) upper layer. However, the driving voltage lines 172 and the first output electrodes 175b may be made of various materials or conductors besides the above.

The lateral sides of the driving voltage lines 172 and the lateral sides of the first output electrodes 175b are inclined with respect to a surface of the substrate 110, and the inclination angle thereof may range from about 30 degrees to about 80 degrees.

A plurality of first gate insulating layers 140p made of silicon nitride or silicon oxide are formed on the driving voltage lines 172, the first output electrodes 175b, and the blocking members 144.

On the first gate insulating layers 140p, a plurality of first control electrodes 124b and a plurality of gate lines 121 are formed.

The first control electrodes 124b are placed on the first semiconductor islands 154b, and respectively include a sustain electrode 127 that forms a storage capacitor Cst by overlapping the driving voltage line 172.

The gate lines 121 transmit the gate signals, and extend substantially in a horizontal direction and intersect the driving voltage lines 172. Each of the gate lines 121 includes a second control electrode 124a branched upward and a wide end portion 129 for connection with another layer or an external driving circuit. When the data driving circuit (not shown) is integrated with the substrate 110, the gate signals 121 may be extended to be directly connected to the gate driving circuit.

The first control electrode 124b and the gate line 121 may be made of an aluminum-(Al) containing metal such as Al and an Al alloy, a silver-(Ag) containing metal such as Ag and a Ag alloy, a copper-(Cu) containing metal such as Cu and a Cu alloy, a molybdenum-(Mo) containing metal such as Mo and an Mo alloy, chromium, tantalum, and titanium. Alternatively, the first control electrode 124b and the gate line 121 may have a multi-layered structure including two conductive layers (not shown), each having a different physical properties. One of the two conductive layers is made of a metal with low resistivity such as an Al-containing metal, a Ag-containing metal, and a Cu-containing metal for reducing signal delay or voltage drop. On the other hand, the other conductive layer is made of a material such as a Mo-containing metal, chromium, titanium, and tantalum, which has good physical, chemical, and electrical contact characteristics with other materials, particularly indium tin oxide (ITO) and indium zinc oxide (IZO). A pair of a chromium lower layer and an Al (alloy) upper layer and a pair of an Al (alloy) lower layer and a Mo (alloy) upper layer are good examples of the combination of the two conductive layers. However, the first control electrode 124b and the gate line 121 may be made of various metals or conductors besides the above.

The lateral sides of the first control electrodes 124b and the lateral sides of the gate lines 121 are inclined with respect to a surface of the substrate 110, and the inclination angle thereof may range from about 30 degrees to about 80 degrees.

A plurality of second gate insulating layers 140q made of silicon oxide or silicon nitride are formed on the first control electrodes 124b and the gate lines 121.

A plurality of second semiconductor islands 154a made of hydrogenated amorphous silicon are formed on the second gate insulating layers 140q. The second semiconductor islands 154a are disposed on the second control electrodes 124a.

A plurality of pairs of ohmic contacts 163a and 165a are formed on the respective second semiconductor islands 154a. The ohmic contacts 163a and 165a are formed in an island shape, and may be made of a material such as n+ hydrogenated amorphous silicon in which an n-type impurity is highly doped.

A plurality of data lines 171 and a plurality of second output electrodes 175a are respectively formed on the ohmic contacts 163a and 165a.

The data lines 171 transmit data signals, and substantially extend in a vertical direction and intersect the gate lines 121. Each of the data lines 171 includes a second input electrode 173a extending toward the second control electrode 124a and a wide end portion 179 for connection with another layer or an external driving circuit. When a data driving circuit (not shown) is directly integrated on the substrate 110, the data lines 171 extend to be directly connected to the data driving circuit.

The second output electrodes 175a are separated from the data lines 171. The second input electrodes 173a and the second output electrodes 175a face each other with respect to the second control electrode 124a.

The data lines 171 and the second output electrodes 175a may be made of the same material as that of the driving voltage lines 172.

The lateral sides of the data lines 171 and the lateral sides of second output electrodes 175a are inclined with respect to a surface of the substrate 110, and the inclination angle thereof may range from about 30 degrees to about 80 degrees.

The ohmic contacts 163a and 165a are interposed only between the underlying second semiconductor islands 154a and the overlying data lines 171 and the second output electrodes 175 thereon, and reduce the contact resistance therebetween. Each of the second semiconductor islands 154a includes a portion that is exposed without being covered with the second input electrode 173a and the second output electrode 175a, such as the portions interposed between the second input electrodes 173a and the second output electrodes 175a.

A passivation layer 180 is formed on the data lines 171, the second output electrodes 175a, and the exposed portions of the second semiconductor islands 154a. The passivation layer 180 includes a lower layer 180p that is made of an inorganic insulator such as silicon nitride or silicon oxide, and an upper layer 180q that is made of an organic insulator. The organic insulator may have photosensitivity and may provide a flat surface. A preferable dielectric constant of the organic insulator is lower than 4.0. The passivation layer 180 may have a single-layered structure including an inorganic insulator or an organic insulator.

The passivation layer 180 has a contact hole 182 that exposes the end portion 179 of the data line 171 and a contact hole 185a that exposes the second output electrode 175a. The passivation layer 180 and the second gate insulating layer 140q have a contact hole 181 that exposes the end portion 129 of the gate line 121 and a contact hole 184 that exposes the first control electrode 124b. The passivation layer 180 and the first and second gate insulating layers 140p and 140q have a contact hole 185b that exposes the first output electrode 175b.

On the passivation layer 180, a plurality of pixel electrode 191, a plurality of connecting members 85, and a plurality of contact assistants 81 and 82 are formed. These members can be made of a transparent conductive material, such as ITO or IZO, or alternatively of a reflective metal, such as Al, Ag, chromium, and alloys thereof.

The pixel electrodes 191 are connected to the first output electrodes 175b through the contact holes 185b, and the connecting members 85 are respectively connected to the first control electrodes 124b and the second output electrodes 175a through the contact holes 184 and 185b.

The contact assistants 81 and 82 are connected to the end portions 129 of the gate lines 121 and the end portions 179 of the data lines 171 through the contact holes 181 and 182, respectively. The contact assistants 81 and 82 complement the adhesive property of the end portions 129 and 179 of the gate lines 121 and the data lines 171 with external devices, and also serve to protect these members.

A partitioning wall 361 is formed on the passivation layer 180. The partitioning wall 361 surrounds edges of the pixel electrodes 191 like a bank, thereby defining openings 365, and is made of an organic or inorganic insulator. The partitioning wall 361 may also be made of a photoresistive material including a black pigment, and in this case, the partitioning wall 361 thus also serves as a light blocking member, and can be formed by a simple process.

Organic light emitting members 370 are formed within the respective openings on the pixel electrodes 191 defined by the partitioning walls 361. Each organic light emitting member 370 is made of an organic material that intrinsically emits light of one of three primary colors (i.e., red, green, and blue). The OLED display displays a desired image as a spatial sum of colored light of the primary colors emitted by the organic light emitting members 370. The organic light emitting members 370 may emit white light, and in this case, each organic light emitting member 370 may be a multi-layered structure that includes a plurality of organic material layers, each emitting a different color among the primary colors. Alternatively, a color filter (not shown) may be formed above or below the organic light emitting member 370.

The organic light emitting members 370 may be multi-layered structures that include an auxiliary layer (not shown) that improves light emitting efficiency of the emission layer in addition to an emission layer (not shown) that actually emits the light. An electron transport layer (not shown) and a hole transport layer (not shown) for balancing electrons and holes, an electron injection layer (not shown) and a hole injection layer (not shown) for enhancing the injection of electrons and holes, or the like, may also be included in the auxiliary layer.

A common electrode 270 is formed on the organic light emitting member 370. A common voltage Vss is applied to the common electrode 270, which is made of a reflective metal, including, e.g., calcium (Ca), barium (Ba), magnesium (Mg), aluminum, silver, or the like, or alternatively of a transparent conductive material, such as ITO or IZO.

In such an OLED display, the pixel electrode 191, the organic light emitting member 370, and the common electrode 270 form the OLED LD. The pixel electrode 191 becomes an anode and the common electrode 270 becomes a cathode, or the pixel electrode 191 becomes a cathode and the common electrode 270 becomes an anode.

In addition, the second control electrodes 124a connected to the gate lines 121 and the second input electrodes 173a and the second output electrodes 175a connected to the data lines 171, together with the second semiconductor islands 154a, form switching thin film transistors (TFTs) Qs. Respective channels of the switching TFTs Qs are formed in the second semiconductor islands 154a between the second input electrodes 173a and the second output electrodes 175a.

The first control electrodes 124b connected to the second output electrodes 175a, the first input electrodes 173b and the ohmic contacts 163a connected to the driving voltage lines 172, and the first output electrodes 175 and the ohmic contacts 165b connected to the pixel electrodes 191, together with the first semiconductor islands 154b, form driving TFTs Qd. Respective channels of the driving TFTs Qd are formed in the first semiconductor islands 154b between the first input electrodes 173 and the first output electrodes 175b.

The first semiconductor islands 154b are made of polycrystalline silicon, and the second semiconductor islands 154a are made of amorphous silicon or polycrystalline silicon.

Such an OLED display displays images by emitting light above or below the substrate 110. Opaque pixel electrodes 191 and a transparent common electrode 270 are used in a top emission type of OLED display, which displays images in an upper direction of the substrate 110, and transparent pixel electrodes 191 and an opaque common electrode 270 are used in a bottom emission type of OLED, which displays image in a lower direction of the substrate 110.

According to another exemplary embodiment of the present invention, each pixel PX may further include another transistor for preventing or complementing deterioration of the OLED LD and the driving TFT Qd in addition to one switching TFT Qs and one driving TFT Qd.

In FIG. 4, the second control electrode 124a is placed on the same layer on which the first input electrode 173b and the first output electrode 175b are formed. In addition, the second gate insulating layer 140q is omitted, and the second input electrode 173a and the second output electrode 175a are formed on the same layer on which the first control electrode 124b is formed.

Therefore, the structure of FIG. 4 is simpler than that of FIG. 3.

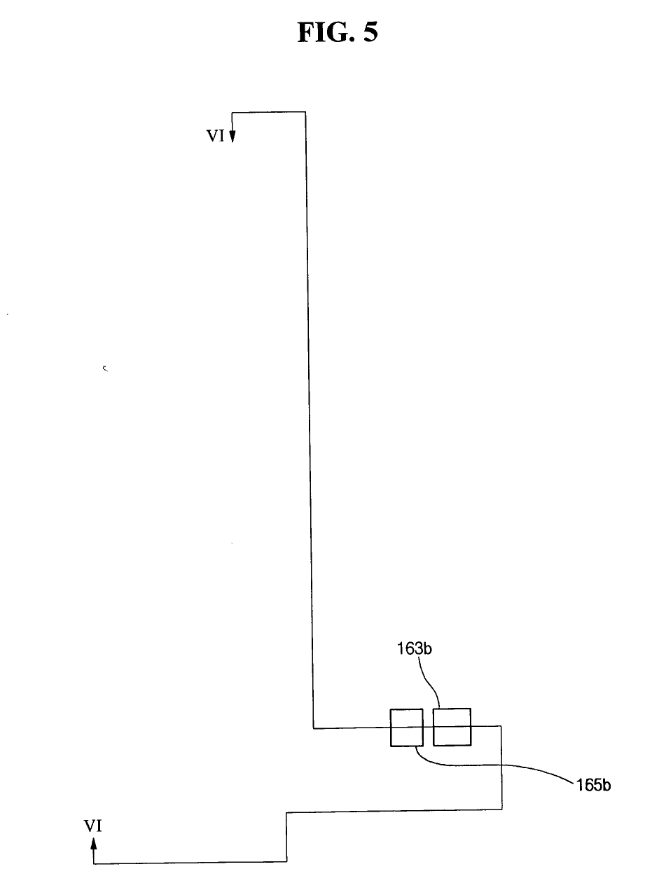

A manufacturing process of the OLED display of FIG. 2 and FIG. 3 will be described in further detail with reference to FIG. 5 to FIG. 20.

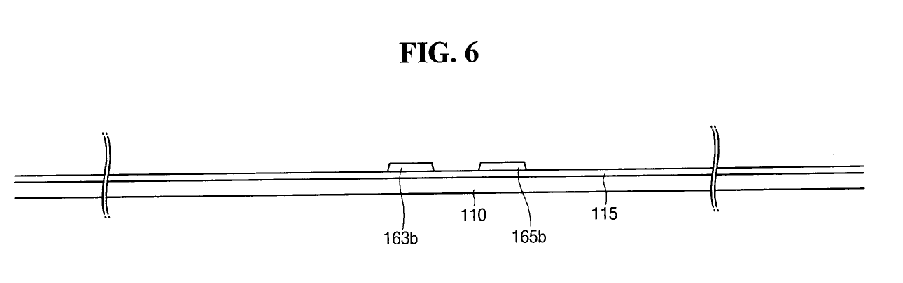

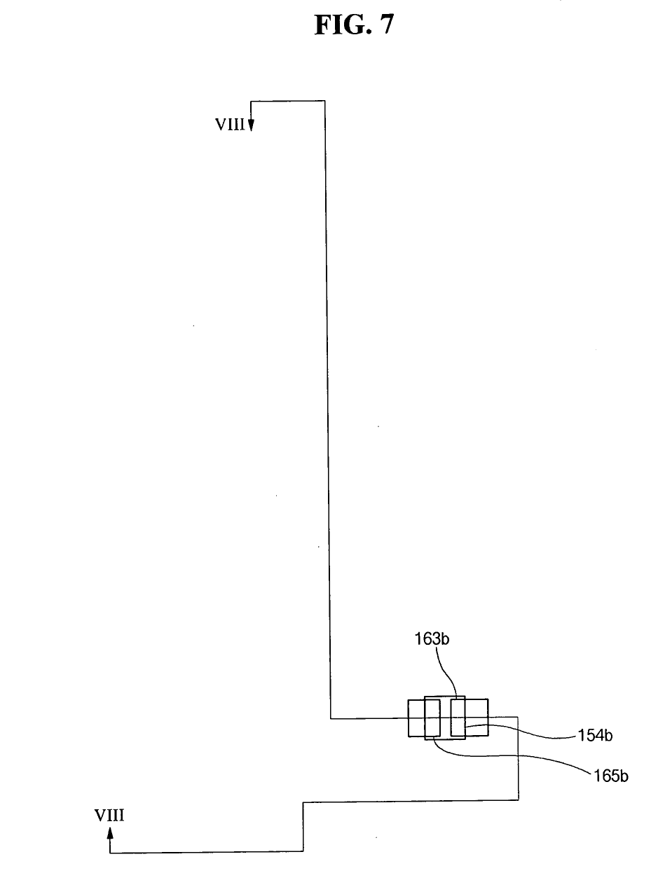

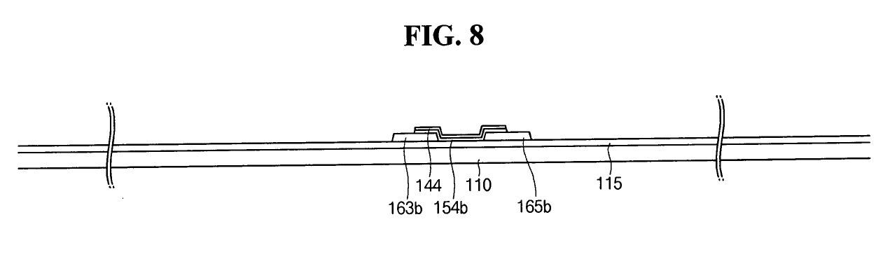

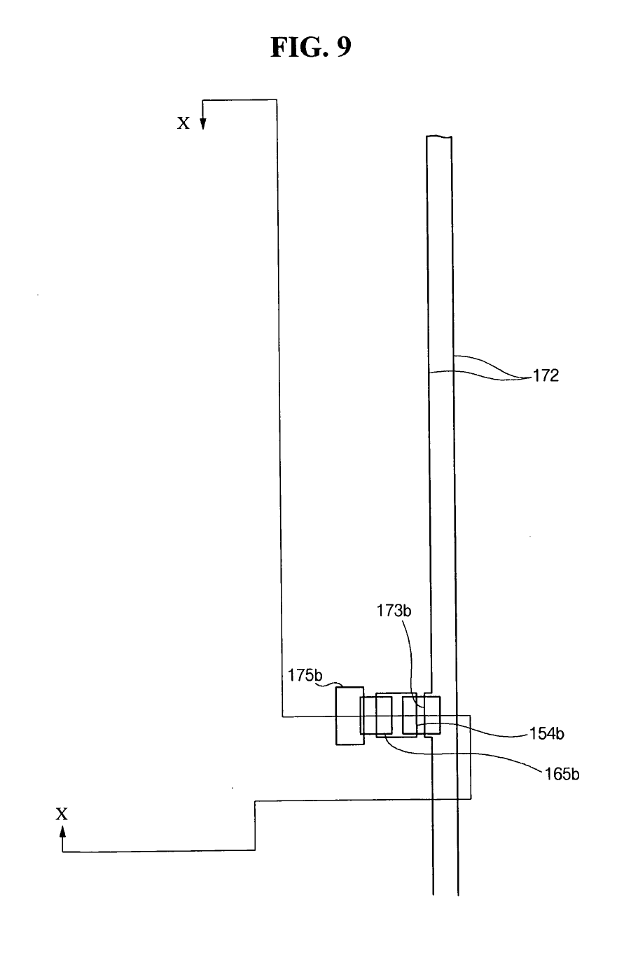

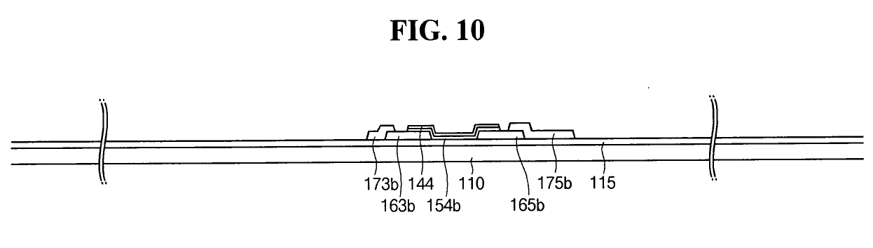

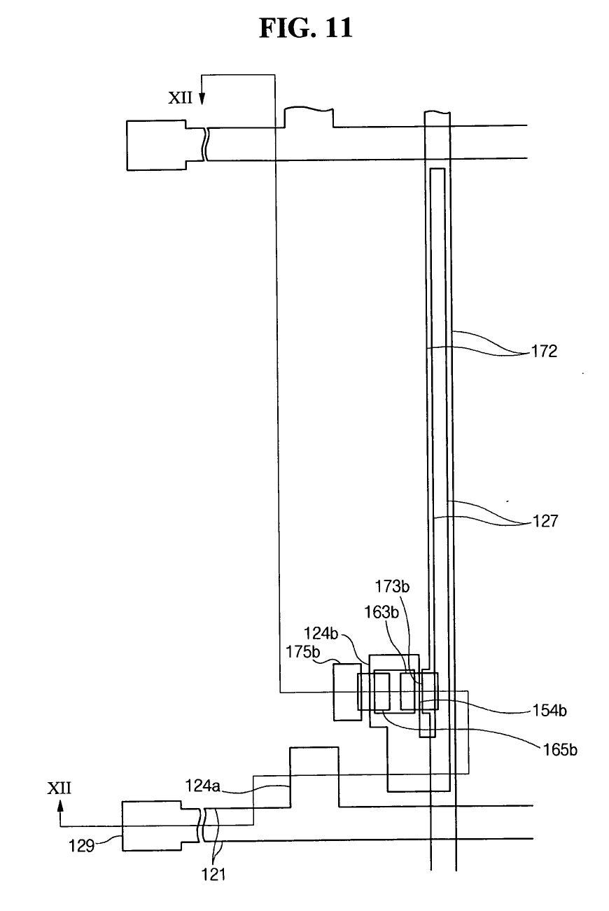

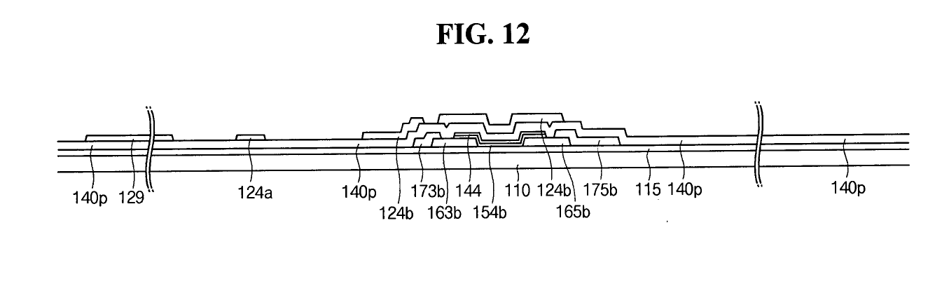

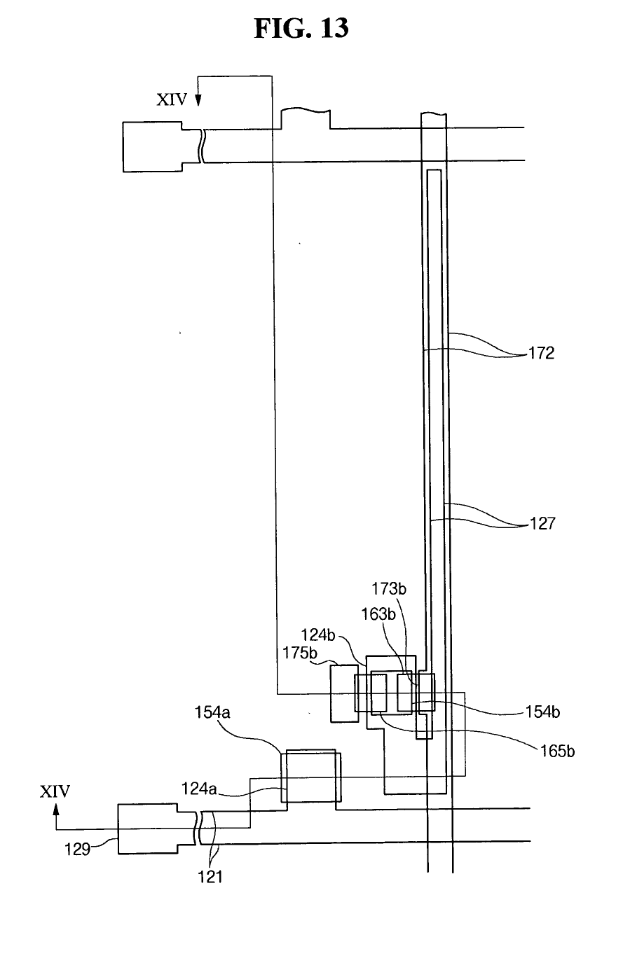

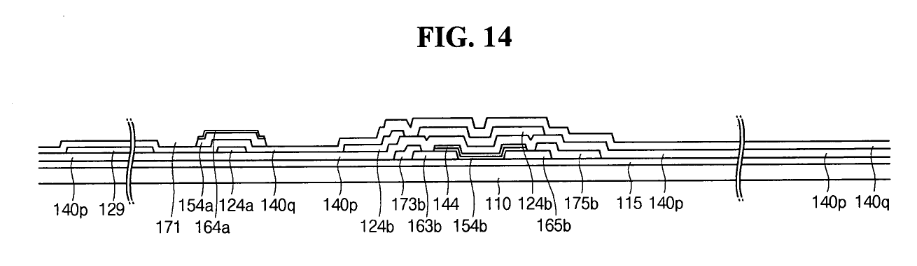

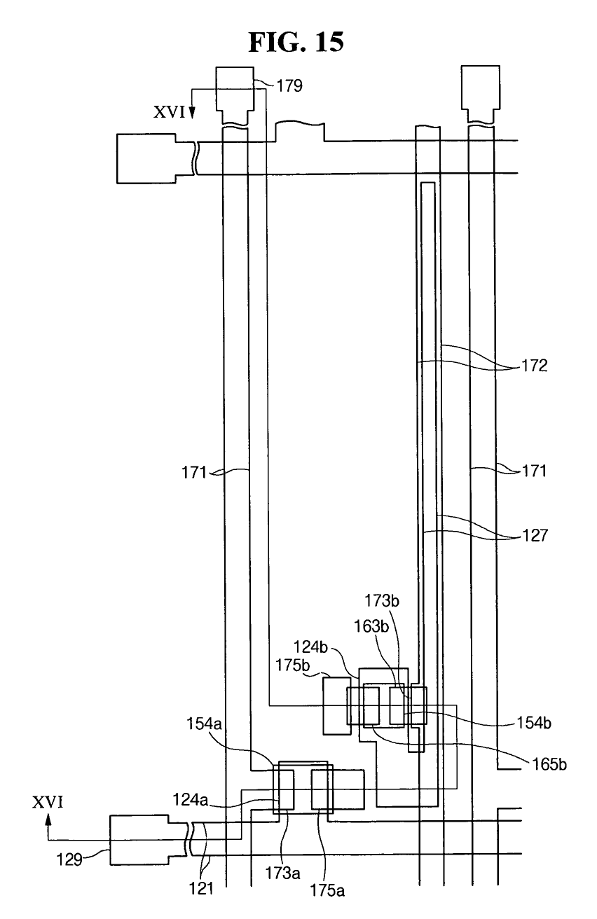

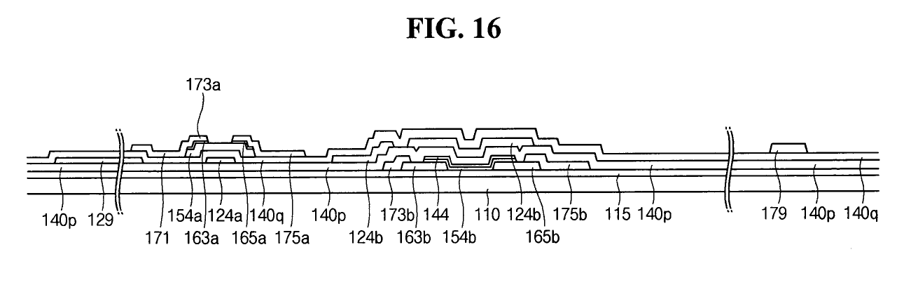

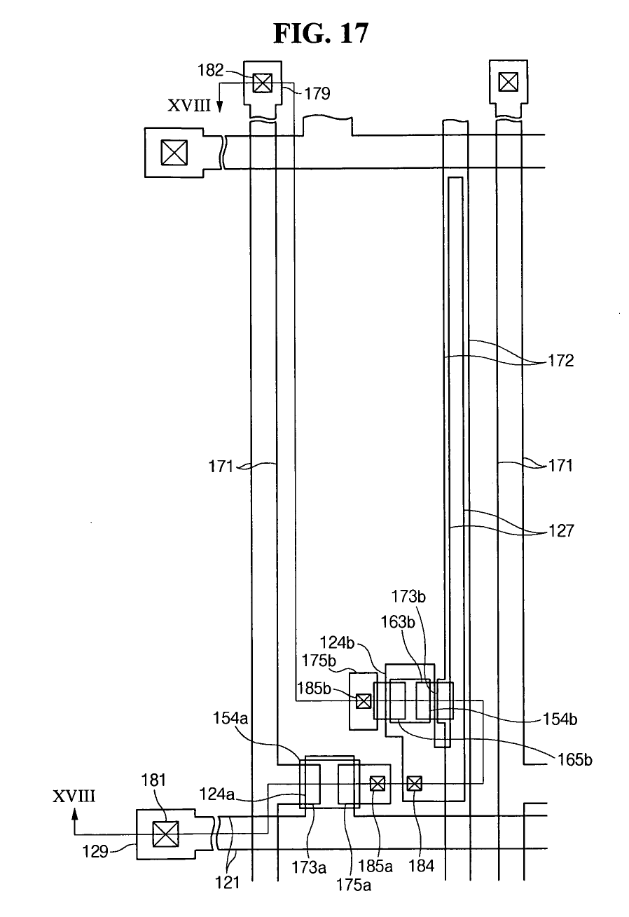

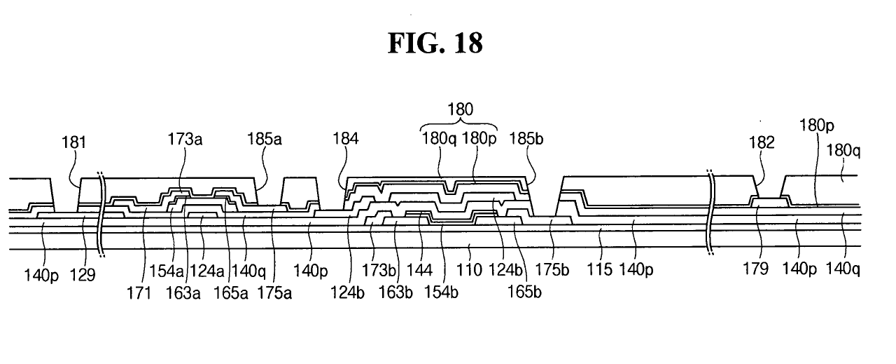

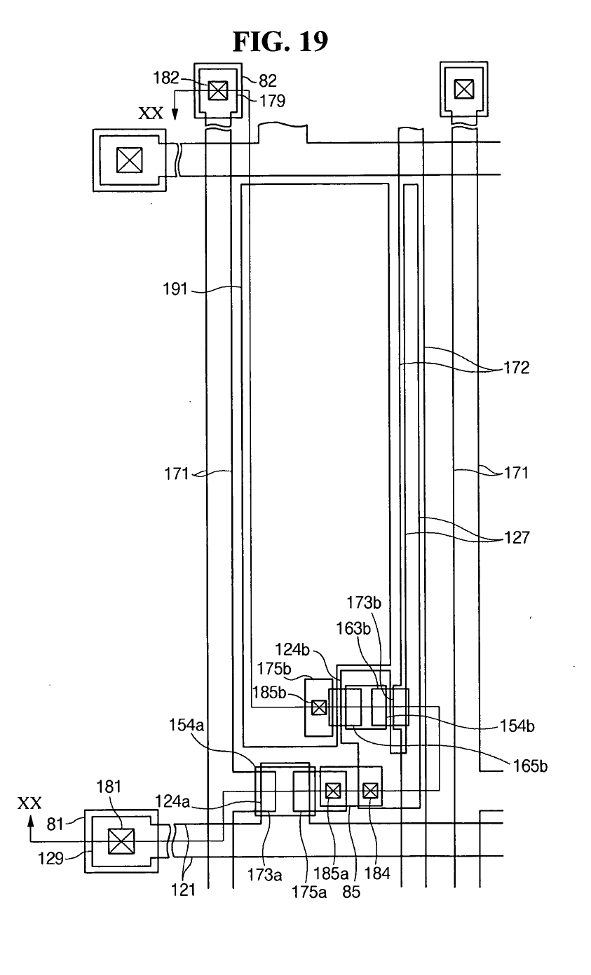

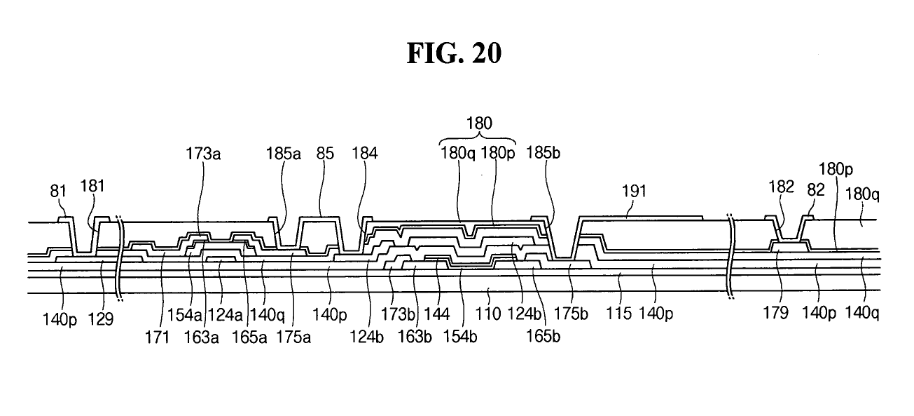

FIG. 5, FIG. 7, FIG. 9, FIG. 11, FIG. 13, FIG. 15, FIG. 17, and FIG. 19 are layout views of intermediate stages of a manufacturing process of the OLED display of FIG. 2 and FIG. 3 according to an exemplary embodiment of the present invention, FIG. 6 is a cross-sectional view of the OLED display of FIG. 5, taken along line VI-VI, FIG. 8 is a cross-sectional view of the OLED display of FIG. 7, taken along line VIII-VIII, FIG. 10 is a cross-sectional view of the OLED display of FIG. 9, taken along line X-X, FIG. 12 is a cross-sectional view of the OLED display of FIG. 11, taken along line XII-XII, FIG. 14 is a cross-sectional view of the OLED display of FIG. 13, taken along line XIV-XIV, FIG. 16 is a cross-sectional view of the OLED display of FIG. 15, taken along line XVI-XVI, FIG. 18 is a cross-sectional view of the OLED display of FIG. 17, taken along line XVIII-XVIII, and FIG. 20 is a cross-sectional view of the OLED display of FIG. 19, taken along line XX-XX.

Referring to FIG. 5 and FIG. 6, the plurality of ohmic contact islands 163b and 165b are formed by sequentially depositing the buffer layer 115 and an impurity semiconductor layer and performing photolithography on the impurity semiconductor layer. The buffer layer 115 is made of silicon oxide, and has the thickness of about 5000 Å. The impurity semiconductor layer is made of amorphous silicon in which an n-type impurity is highly doped, and has the thickness of about 100 Å to 3000 Å, for example, of about 1000 Å.

Referring to FIG. 7 and FIG. 8, a SiOF blocking layer having a thickness of about 500 Å and a SiOF blocking layer having a thickness of several tens to several hundreds of Å are sequentially deposited by using a chemical vapor deposition (CVD) method, or the like.

Subsequently, a photosensitive film is formed on the blocking layer and the photosensitive film is exposed and developed. Then, the blocking layer and the amorphous silicon layer are simultaneously dry-etched by using the processed photosensitive film as a mask, thereby forming the plurality of blocking members 144 and the plurality of first semiconductor islands 154b, and at the same time the ohmic contacts 163b and 165b are exposed.

The ohmic contacts 163b and 165b and the first semiconductor islands 154b are crystallized by using a field-enhanced rapid thermal annealing (FE-RTA) method, and the like.

In this case, fluorine included in the blocking member 144 reduces defects inside the first semiconductor island 154b. In further detail, due to heat during the crystallization process, hydrogen contained in the first semiconductor island 154b is reduced so that internal defects (e.g., dangling bonds) of the first semiconductor island 154b may increase. Therefore, fluorine included in the blocking member 144 is dispersed therein so as to fill in the vacancy of the hydrogen, thereby preventing the increase of internal defects.

When an impurity is dissolved into a channel unit of the first semiconductor island 154b, the impurity can be removed by shaving a surface of the channel unit. However, in order to shave the surface of the channel unit, the thickness of the first semiconductor island 154b needs to be thick enough during the deposition process, and the uniformity of the thickness may be decreased after the shaving. Therefore, the first semiconductor island 154b can have a thickness of less than 500 Å since the shaving process is not required according to the present exemplary embodiment.

In addition, a typical TFT manufacturing method forms the ohmic contacts 163b and 165b on the first semiconductor island 154b and the channel unit of the first semiconductor island 154b can be easily damaged since a surface of the channel unit is exposed when the ohmic contacts 163b and 165b are formed on the first semiconductor island 154b by using a plasma dry-etching method, but this problem does not occur in the present exemplary embodiment.

Since the heat treatment crystallization process is performed after the ohmic contacts 163b and 165b and the first semiconductor island 154b are completely shaped, deformation of the substrate due to the heat treatment can be prevented, thereby preventing an erroneous alignment problem.

The blocking member 144 can prevent the first semiconductor island 154b from being damaged in a subsequent process.

Referring to FIG. 9 and FIG. 10, a metal layer is deposited and then subjected to photolithography so as to form the plurality of driving voltage lines 172 and the plurality of first output electrodes 175b. Since the blocking member 144 containing fluorine that hardly responds to a metal is interposed between the driving voltage line 172 and the first semiconductor island 154b, a defect due to reaction of the metal and the semiconductor can be prevented.

Referring to FIG. 11 and FIG. 12, after depositing the first gate insulating layer 140p, the plurality of first control electrodes 124b and the plurality of gate lines 129 that include the second control electrodes 124a and the end portions 129 are formed.

Referring to FIG. 13 and FIG. 14, after sequentially depositing the second gate insulating layer 140q, an intrinsic amorphous silicon layer, and an impurity amorphous silicon layer, the impurity silicon layer and the intrinsic silicon layer are subjected to photolithography so as to form a plurality of impurity semiconductor islands 164a and the plurality of second semiconductor islands 154a.

Referring to FIG. 15 and FIG. 16, a metal layer is deposited and then subjected to photolithography so as to form the plurality of data lines 171 including the second input electrodes 173a and the end portions 179, and the plurality of second output electrodes 175a. Subsequently, the plurality of ohmic contact islands 163a and 165a are completely formed by removing portions of the impurity semiconductors 164a that are not covered with the second input electrodes 173a and the second output electrodes 175a and are thus exposed, and the second semiconductor islands 154a provided therebelow are thereby partially exposed. Then, the surface of the exposed portions of the second semiconductors 154a can be stabilized by O₂ plasma.

Referring to FIG. 17 and FIG. 18, the passivation layer 180 including the lower layer 180p and the upper layer 180q is deposited and then subjected to photolithography, together with the first and second gate insulating layers 140p and 140q, so as to form the plurality of contact holes 181, 182, 184, 185a, and 185b. The contact holes 181, 182, 184, 185a, and 185b expose the end portions of the gate lines 121, the end portions of the data lines 171, the first control electrodes 124b, the second output electrodes 175a, and the first output electrodes 175b, respectively.

Referring to FIG. 19 and FIG. 20, the plurality of pixel electrodes 191, the plurality of connecting members 85, and the plurality of contact assistants 81 and 82 are formed on the passivation layer 180.

Referring to FIG. 2 and FIG. 3, the partitioning wall 361 having the plurality of openings 365 is formed, and the organic light emitting member 370 and the common electrode 270 are formed.

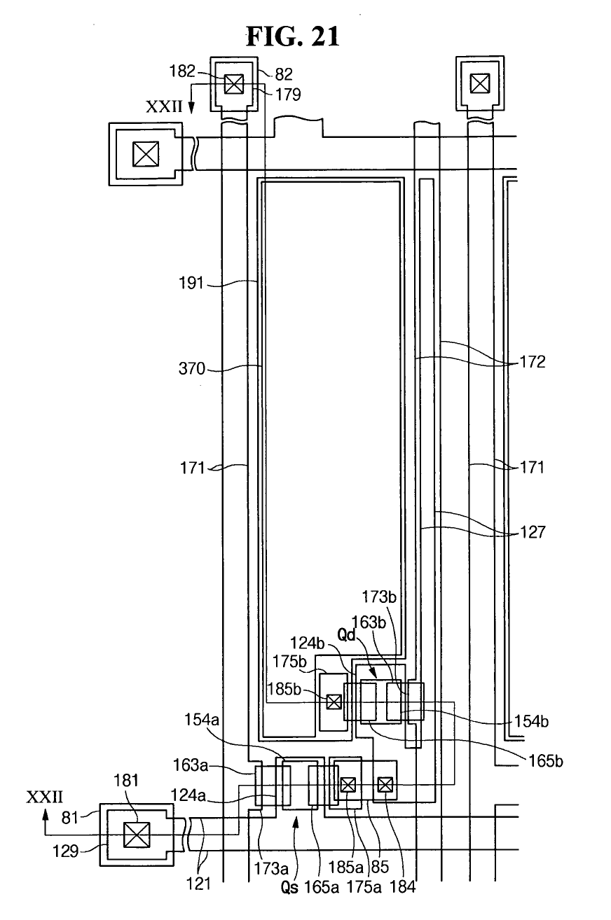

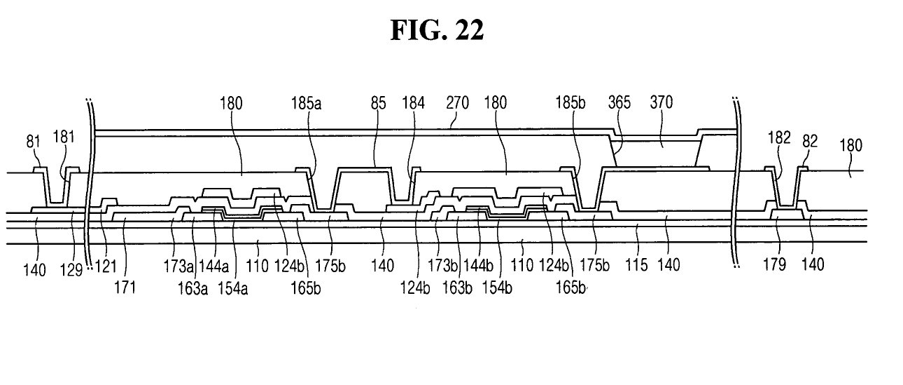

An OLED display according to another exemplary embodiment of the present invention is described below in further detail with reference to FIG. 21 and FIG. 22.

FIG. 21 is a layout view of an OLED display according to another exemplary embodiment of the present invention, and FIG. 22 is a cross-sectional view of the OLED display of FIG. 21, taken along line XXII-XXII.

As shown in FIG. 21 and FIG. 22, a cross-sectional structure of the OLED display according to another exemplary embodiment is similar to that of the OLED display of FIG. 2 to FIG. 4. However, a switching thin film transistor Qs and the driving TFT Qd substantially have the same cross-section structure, and accordingly, the structure of other portions are changed.

In further detail, a plurality of pairs of first ohmic contacts 163b and 165b and a plurality of pairs of second ohmic contacts 163a and 165a are formed on a buffer layer 115 that is formed on a substrate 110. A plurality of first blocking members 144b are formed on a plurality of first semiconductor islands 154b that are formed on the first ohmic contacts 163b and 165b, and a plurality of second blocking members 144a are formed on a plurality of second semiconductor islands 154a that are formed on the second ohmic contacts 163a and 165a.

On the buffer layer 115 and the ohmic contacts 163b and 165b, a plurality of driving voltage lines 172 including a plurality of first input electrodes 173b, a plurality of data lines 171 including a plurality of second input electrodes 173a, and a plurality of first output electrodes 175b and a plurality of second output electrodes 175a are formed.

A plurality of gate insulating layers 140 are formed on the data lines 171, the driving voltage lines 172, the output electrodes 175b and 175a, and the blocking members 144b and 144a.

A plurality of first control electrodes 124b including a plurality of sustain electrodes 127 and a plurality of gate lines 121 including a plurality of second control electrodes 124a are formed on the gate insulating layers 140. A plurality of first control electrodes 124b are formed on the second semiconductors 154a, and a plurality of second control electrodes 124a are formed on the second semiconductors 154a.

A single-layered passivation layer 180 is formed on the first control electrodes 124b and the gate lines 121, and a plurality of contact holes 181 exposing end portions 129 of the gate lines 121 and a plurality of contact holes 184 exposing the first control electrodes 124b are formed on the passivation layer 180. A plurality of contact holes 182 exposing end portions 179 of the data lines 171, a plurality of contact holes 185a exposing the second output electrodes 175a, and a plurality of contact holes 185b exposing the first output electrodes 175b are formed on the passivation layer 180 and the gate insulating layers 140.

A plurality of pixel electrodes 191, a plurality of connecting members 85, a plurality of pairs of ohmic contacts 81 and 82, and a plurality of partitioning walls 361 are formed on the passivation layer 180. The partitioning walls 361 have a plurality of openings 365 and a plurality of organic light emitting members 370 are formed therein.

A common electrode 270 is formed on the organic light emitting members 370.

In such an OLED display, respective switching TFTs Qs include a second control electrode 124a, a second input electrode 173a, a second output electrode 175a, and a second semiconductor island 154a.

In the case of the structure of FIG. 21 and FIG. 22, the switching TFT Qs and the driving TFT Qd are formed on the same layer with the same structure, and therefore, they can be formed by a simple manufacturing process.

An OLED display having other structures can be applied to the exemplary embodiments of the present invention.

As described, a crystallization process is performed after an ohmic contact is formed first and a semiconductor is formed, and therefore damage to the semiconductor, introduction of an impurity, and erroneous alignment due to deformation of a substrate can be reduced.

In addition, a defect of the semiconductor can be reduced and a defect of the OLED display due to contact with a metal can be reduced by using an insulating layer containing fluorine.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor comprising:
first and second ohmic contacts formed on a substrate;
a semiconductor member formed on the first and second ohmic contacts and the substrate;
a blocking member formed on the semiconductor member;
an input electrode formed on the first ohmic contact;
an output electrode formed on the second ohmic contact;
an insulating layer formed on the input electrode, the output electrode, and the blocking member; and
a control electrode formed on the insulating layer and overlapping the semiconductor member.

2. The thin film transistor of claim 1, wherein the semiconductor member includes polycrystalline silicon.

3. The thin film transistor of claim 2, wherein the first and second ohmic contacts include polycrystalline silicon that contains an impurity.

4. The thin film transistor of claim 3, wherein the blocking member includes fluorine.

5. The thin film transistor of claim 4, wherein the blocking member includes SiOF.

6. The thin film transistor of claim 5, wherein the blocking member and the semiconductor member have substantially the same planar shape.

7. The thin film transistor of claim 1, wherein the input electrode and the outputelectrode are spaced apart from the semiconductor member.

8. An organic light emitting diode (OLED) display comprising:
a pair of first ohmic contacts formed on a substrate;
a first semiconductor member formed on the first ohmic contacts and the substrate;
a blocking member formed on the first semiconductor member;
a first input electrode formed on one of the first ohmic contracts;
a first output electrode formed on the other of the first ohmic contacts;
a first insulating layer formed on the first input electrode, the first output electrode, and the blocking member;
a first control electrode formed on the first insulating layer and overlapping the first semiconductor member;
a second control electrode formed on the first insulating layer, and separated from the first control electrode;
a second insulating layer formed on the first and second control electrodes;
a second semiconductor member formed on the second insulating layer and overlapping the second control electrode;
a pair of second ohmic contacts formed on the second semiconductor member;
a second input electrode formed on one of the second ohmic contacts;
a second output electrode formed on the other of the second ohmic contacts; and
an organic light emitting diode connected to the first output electrode.

9. The OLED display of claim 8, wherein the first semiconductor member includes polycrystalline silicon.

10. The OLED display of claim 9, wherein the second semiconductor includes amorphous silicon.

11. The OLED display of claim 10, wherein the first ohmic contacts include polycrystalline silicon containing an impurity.

12. The OLED display of claim 11, wherein the blocking member includes fluorine.

13. The OLED display of claim 12, wherein the blocking member includes SiOF.

14. The OLED display of claim 13, wherein the blocking member and the first semiconductor have the same planar shape.

15. The OLED display of claim 8, wherein the first control electrode and the second output electrode are connected to each other.

16. A manufacturing method of a thin film transistor, the manufacturing method comprising:
forming a pair of ohmic contacts including amorphous silicon that contains an impurity;
forming a semiconductor member including amorphous silicon;
forming a blocking member on the semiconductor member;
crystallizing the ohmic contacts and the semiconductor member;
forming an input electrode and an output electrode on the ohmic contacts;
forming an insulating layer on the input electrode, the output electrode, and the blocking member; and
forming a control electrode on the insulating layer.

17. The manufacturing method of claim 16, wherein the semiconductor member comprises hydrogen before the crystalization.

18. The manufacturing method of claim 17, wherein the crystallizing of the ohmic contacts and the semiconductor member comprises performing heat treatment on the ohmic contacts and the semiconductor member.

19. The manufacturing method of claim 18, wherein the blocking member includes fluorine.

20. The manufacturing method of claim 19, wherein the blocking member includes SiOF.

21. The manufacturing method of claim 20, wherein both the blocking member and the semiconductor member are formed by a single photolithographic process.

22. A manufacturing method of an organic light emitting diode (OLED) display, the manufacturing method comprising:
forming a pair of ohmic contacts including amorphous silicon that contains an impurity;
forming a semiconductor including amorphous silicon;
forming a blocking member on the semiconductor member;
crystallizing the ohmic contacts and the semiconductor member;
forming an input electrode and an output electrode on the ohmic contacts;
forming an insulating layer on the input electrode, the output electrode, and the blocking member;
forming a control electrode on the insulating layer;
forming a switching thin film transistor; and
forming an organic light emitting diode connected to the output electrode.
